(19) United States
(12) Patent Application Publication
(10) Pub. No.: US 2025/0118558 A1
(43) Pub. Date: Apr. 10, 2025

(54) MASK PATTERN AND METHOD OF FORMING A FINE PATTERN OF A SEMICONDUCTOR DEVICE USING THE SAME

(71) Applicant: SK hynix Inc., Gyeonggi-do (KR)

(72) Inventor: Hong Gu LEE, Gyeonggi-do (KR)

(21) Appl. No.: 18/650,095

(22) Filed: Apr. 30, 2024

(30) Foreign Application Priority Data
Oct. 5, 2023 (KR) 10-2023-0132708

(51) Int. Cl. H01L 21/033; H01L 21/311; H01L 23/13

(52) U.S. Cl. CPC H01L 21/0337; H01L 21/0332; H01L 21/31111; H01L 21/31144; H01L 23/13

(57) ABSTRACT

A mask pattern may include a first spacer and a second spacer. The first spacer may be formed over a layer. The second spacer may be formed over the first spacer. The first spacer and the second spacer may define a mesh structure having a plurality of opened regions. The opened regions may be etched to form a hole array region and a plurality of dummy holes in the layer. The hole array region may include a plurality of holes. The dummy holes may be configured to surround the hole array.

### CROSS-REFERENCES TO RELATED APPLICATION

The present application claims priority under 35 U.S.C. § 119(a) to Korean application number 10-2023-0132708, filed on, Oct. 5, 2023, which is incorporated herein by reference in its entirety.

### BACKGROUND

### 1. Technical Field

Various embodiments of the present disclosure generally relate to a mask pattern and a method of forming a fine pattern of a semiconductor device using the same.

### 2. Related Art

As a design rule of a semiconductor device, size reduction requires higher integration degree, finer patterns, and improved manufacturing technologies for forming the finer patterns. The current state of the art of semiconductor devices requires forming a fine pattern having a pitch below the resolution of existing exposure apparatuses. Hence, for further reduction in the size of semiconductor devices various methods for manufacturing finer patterns are currently being studied.

Recently, a method of manufacturing a fine pattern may employ spacer patterning technology (SPT) and double patterning technology (DPT). Furthermore, at least one of the SPT and DPT are used to form a storage node contact hole having a fine size.

### SUMMARY

Various embodiments of the present disclosure provide a mask pattern that may be capable of forming storage contact holes without a bridge error.

Various embodiments of the present disclosure, also provide a method of forming a fine pattern of a semiconductor device using the mask pattern with improved electrical characteristics.

According to embodiments of the present disclosure, there may be provided a mask pattern. The mask pattern may include a first spacer and a second spacer. The first spacer may be formed on a layer. The second spacer may be formed on the first spacer. The first spacer and the second spacer may define a mesh structure having a plurality of opened regions. The opened regions may be etched to form a hole array region and a plurality of dummy holes in the layer. The hole array may include a plurality of holes. The dummy holes may be configured to surround the hole array. At least one of the first spacer and the second spacer may include a diagonal pattern portion and an indented pattern portion. The diagonal pattern portion may be extended in a diagonal line inclined to an imaginary line, which may be connected between center points of holes in the hole array arranged in a horizontal direction, at an angle. The indented pattern portion may be formed at both ends of the diagonal pattern portion. The indented pattern portion may be extended in the horizontal direction or a longitudinal direction. The at least one of the first spacer and the second spacer may include a plurality of loop-shaped patterns having an opened upper surface and an opened lower surface.

According to embodiments of the present disclosure, there may be provided a method of forming a fine pattern of a semiconductor device. In the method of forming the fine pattern of the semiconductor device, a layer may be prepared. A lower hard mask pattern may be formed on the layer. The lower hard mask pattern may include a first spacer with a plurality of loop-shaped patterns. An upper hard mask pattern may be formed on the lower hard mask pattern to form a mesh structure including a plurality of opened regions. The upper hard mask pattern may include a second spacer with a plurality of loop-shaped patterns. A mask may be formed over a part of an edge region of the mesh structure to define a dummy hole region. The plurality of the opened regions may be etched to form a hole array and a plurality of dummy holes in the layer. At least one of the first spacer and the second spacer may include a diagonal pattern portion and an indented pattern portion. The diagonal pattern portion may be extended in a diagonal line inclined to an imaginary line, which may be connected between center points of holes in the hole array arranged in a horizontal direction, at an angle. The indented pattern portion may be formed at both ends of the diagonal pattern portion. The indented pattern portion may be extended in the horizontal direction or a longitudinal direction. The at least one of the first spacer and the second spacer may include a plurality of loop-shaped patterns having an opened upper surface and an opened lower surface.

According to embodiments of the present disclosure, there may be provided a semiconductor device. The semiconductor device may include a hole array region and a dummy hole region. The hole array region may include a plurality of holes repeatedly arranged by a first pitch along a first diagonal line and a second diagonal line intersected with the first diagonal line. The dummy hole region may include a plurality of first dummy holes and a plurality of second dummy holes. The first dummy holes may be arranged over and under an edge region of the hole array region. The first dummy holes may be repeatedly arranged by a second pitch. The second dummy holes may be arranged left and right the edge region of the hole array region. The second dummy holes may be repeatedly arranged by a third pitch.

In embodiments of the present disclosure, an intersected angle between the first diagonal line and the second diagonal line may be from about 50° to about 70°.

In embodiments of the present disclosure, the holes may be repeatedly arranged along a horizontal direction by a fourth pitch. The first pitch may be substantially the same as or different from the fourth pitch.

In embodiments of the present disclosure, a size of each of the first dummy holes may be different from a size of each of the second dummy holes.

According to embodiments of the present disclosure, the mask pattern may use the spacer. The spacer may include the two diagonal patterns, the indented pattern extended from the two ends of the diagonal pattern in the horizontal direction or the longitudinal direction, and the loop-shaped patterns with the openings. The mask pattern may use the spacer to secure an SPC process margin. The mask pattern may function by preventing a parasitic hole and a normal hole at the edge region of the hole array region from not being opened when forming the fine pattern.

Furthermore, the mask pattern may utilize the mask configured to determine the opening of the indented pattern in the loop-shaped pattern so that a size of the opened region may be controlled to variously control a size of the dummy hole. Thus, the mask pattern may prevent an edge error of the hole array and a bridge between the holes.

Furthermore, the method of forming the fine pattern of the semiconductor device using the mask pattern may form the semiconductor device with the fine pattern having improved electrical characteristics.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a plan view illustrating a hole array formed according to the mesh spacer patterning method used for forming a storage node in accordance with an embodiment of the present disclosure;

FIG. 2 is a plan view illustrating a structure in which a mask for removing undesired holes is formed on the hole array of FIG. 1;

FIG. 3A is a SEM (scanning electron microscope) image illustrating parasitic holes in the hole array formed according to the mesh spacer patterning method in accordance with an embodiment of the present disclosure;

FIG. 3B is a SEM image illustrating non-opened holes in the hole array formed according to the mesh spacer method in accordance with an embodiment of the present disclosure;

FIG. 4 is a SEM image illustrating a bridge at an edge region of the hole array formed according to the mesh spacer method in accordance with an embodiment of the present disclosure;

FIG. 5 is a plan view illustrating a mask pattern with a first mesh structure in accordance with embodiments of the present disclosure;

FIG. 6 is a plan view illustrating a mask pattern with a second mesh structure in accordance with embodiments of the present disclosure;

FIG. 7 is a plan view illustrating a first spacer formed on an etching target layer according to embodiments in accordance with an embodiment of the present disclosure;

FIG. 8A is an enlarged plan view illustrating a first loop-shaped pattern of the first spacer of FIG. 7;

FIG. 8B is an enlarged plan view illustrating a second loop-shaped pattern of the first spacer of FIG. 7;

FIG. 9 is a plan view illustrating a 2-1 spacer formed on the etching target layer according to embodiments of the present disclosure;

FIG. 10 is a plan view illustrating a mask pattern with a mask on a first mesh structure in accordance with embodiments of the present disclosure;

FIG. 11 is a plan view illustrating a part region of an etching targe layer with a hole array and dummy holes formed using a mask on a first mesh structure in accordance with embodiments of the present disclosure;

FIG. 12 is a plan view illustrating a part of an etching target layer with a hole array and dummy holes formed by a first mesh structure in accordance with embodiments of the present disclosure;

FIG. 13 is a plan view illustrating a 2-2 spacer formed on an etching target layer with a 2-2 spacer in accordance with embodiments of the present disclosure;

FIG. 14 is a plan view illustrating a mask pattern with a mask on a second mesh structure in accordance with embodiments of the present disclosure;

FIG. 15 is a plan view illustrating a part region of an etching targe layer with a hole array and dummy holes formed using a mask on a second mesh structure in accordance with embodiments of the present disclosure;

FIG. 16 is a flow chart of a method of forming a fine pattern of a semiconductor device in accordance with embodiments of the present disclosure;

FIGS. 17 to 26 are perspective views illustrating a method of forming a first mesh structure in accordance with embodiments of the present disclosure;

FIGS. 27 to 31 are perspective views illustrating a method of forming a second mesh structure in accordance with embodiments of the present disclosure; and

FIGS. 32 and 33 are plan views illustrating a semiconductor device with a layer in accordance with embodiments of the present disclosure.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the scope of the present disclosure as defined in the appended claims.

The present invention is described herein with reference to cross-section and/or plan illustrations of embodiments of the present disclosure. However, embodiments of the present disclosure should not be construed as limiting the inventive concept. Although a few embodiments of the present disclosure will be shown and described, it will be appreciated by those of ordinary skill in the art that changes may be made in these embodiments without departing from the principles of the present disclosure.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, spatially relative terms, such as “beneath,” “below,” “bottom,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the phrase “coupled to” and “connected to” refer to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

A spacer patterning technology (SPT) may form a spacer for patterning an etching target layer. The spacer structure includes a line width below a resolution of an exposure apparatus.

In order to form a mask pattern with a plurality of holes such as storage node contact holes using the SPT, an immersion lithography such as an ArF (argon/fluoride) immersion may be used. However, since it is not possible to form a mask pattern comprising holes arranged below 30 nm pitch by the SPT based on the ArF immersion, a mesh spacer patterning technology (Mesh SPT) is proposed.

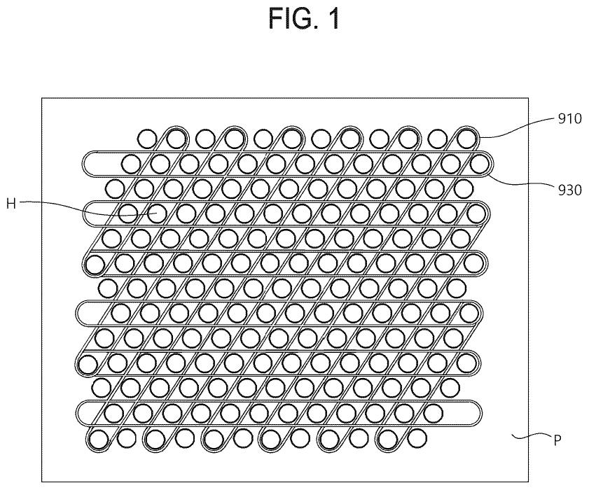

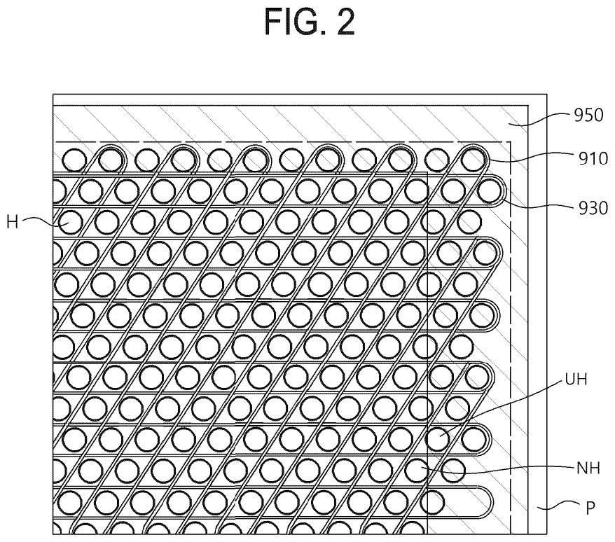

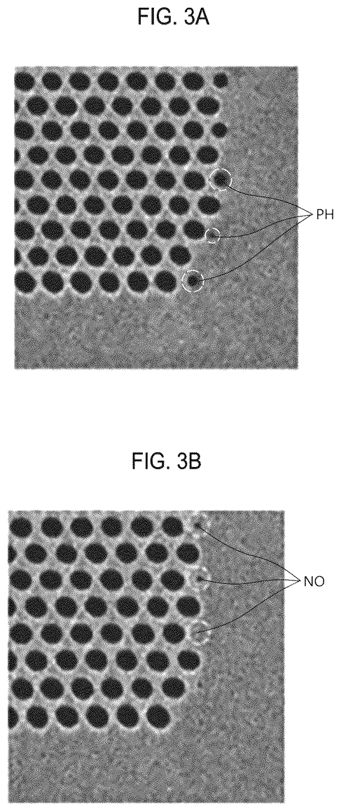

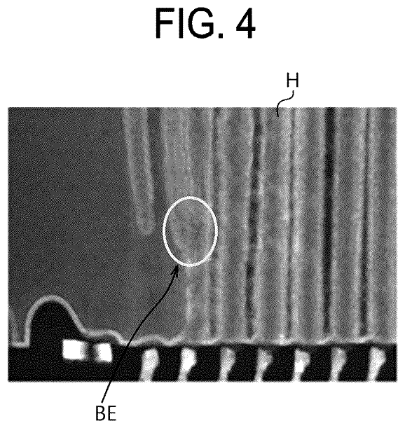

In accordance with embodiments of the present disclosure, FIG. 1 is a plan view illustrating a hole array formed according to the mesh spacer patterning method used for forming a storage node, FIG. 2 is a plan view illustrating a structure in which a mask for removing undesired holes is formed on the hole array of FIG. 1, FIG. 3A is a SEM (scanning electron microscope) image illustrating parasitic holes in the hole array formed according to the mesh spacer patterning method, FIG. 3B is a SEM image illustrating non-opened holes in the hole array formed according to the mesh spacer method, and FIG. 4 is a SEM image illustrating a bridge at an edge region of the hole array formed according to the mesh spacer method.

Referring to FIG. 1, at least one first spacer 910 extends to a first direction. At least one second spacer 930 extends to a second direction different from the first direction. For example, the second spacer 930 extends to pass over the first spacer 910. The first spacer 910 and the second spacer 930 may form a mesh structure. Furthermore, a region to form a hole is defined at a cross point between the first spacer 910 and the second spacer 930. For example, the arrangement of the holes can be defined as a hole array and the above method for forming the hole array may refer to a mesh spacer patterning method.

Referring to FIG. 2, the hole array may include undesired holes UH in an edge portion of the hole array. A SPC (SN peri close) mask 950 may cover an edge portion of the hole array to prevent the undesired holes UP from being formed in the edge region of the hole array. Here, the edge region may be a boundary region of a cell array region including the hole array and a peripheral region P where peripheral circuits are integrated.

In a 6F2 layout with diagonal cells of a DRAM (dynamic random access memory) device, holes H for storage nodes may be arranged in a zigzag shape. Accordingly, in a 6F2 layout normal holes NH and the undesired holes UH are continuously arranged with a fine pitch.

This may cause parasitic holes PH (see FIG. 3A) where undesired holes are not removed, depending on a position of the SPC mask 950, or a non-opened hole (NO) may occur (See FIG. 3B). The not opened hole is a phenomenon in which an abnormal hole is formed in the position where the normal hole NH should be formed.

In addition, as shown in FIG. 4, as described above, the parasitic hole (PH), the non-opened holes (NO) or a bridge error (BE) are generated. The bridge error BE refers to a phenomenon in which a defect occurs during hole formation and a plurality of adjacent holes (H) are connected at the lower end.

In order to control the error, it may be required to prevent generation of parasitic and non-opened holes PH, NO by securing the SPC process margin.

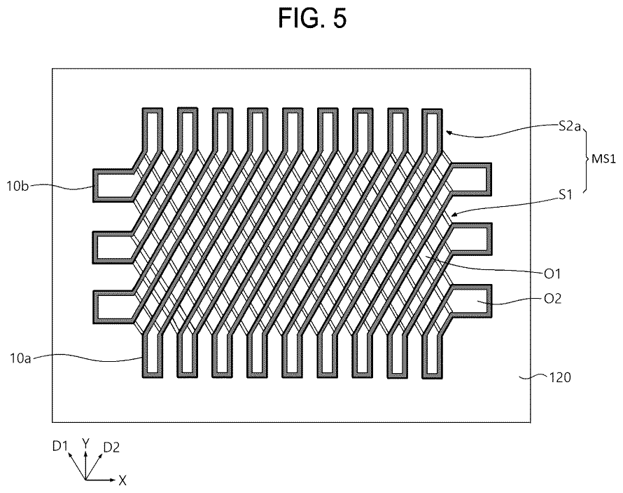

FIG. 5 is a plan view illustrating a mask pattern with a first mesh structure in accordance with embodiments of the present disclosure.

Referring to FIG. 5, a mask pattern of embodiments may include a first mesh structure MS1. The first mesh structure MS1 may include a first spacer S1 and a 2-1 spacer S2a. The 2-1 spacer S2a may be formed on the first spacer S1. The first mesh structure MS1 may define a plurality of first openings O1 and a plurality of second openings O2 formed by the first spacer S1 and the 2-1 spacer S2a.

The first spacer S1 may face the 2-1 spacer S2a. The first spacer S1 and the 2-1 spacer S2a may be symmetrical linearly with respect to a horizontal direction X or a longitudinal direction Y.

For example, the first spacer S1 may be formed by a first SPT process. The 2-1 spacer S2a may be formed by a second SPT process. The first SPT process and the second SPT process may be illustrated in detail later.

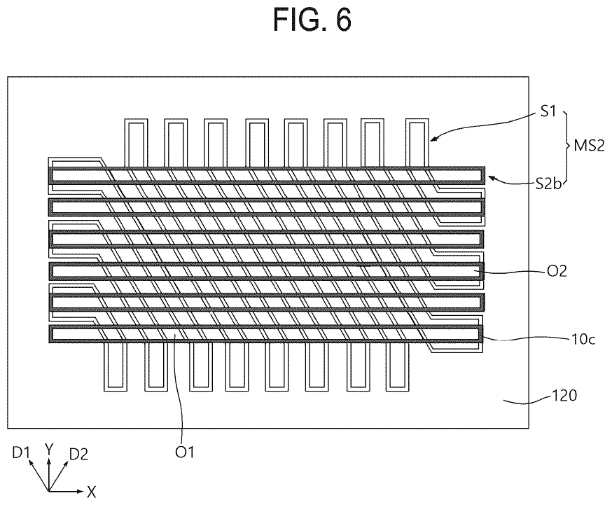

FIG. 6 is a plan view illustrating a mask pattern with a second mesh structure in accordance with embodiments of the present disclosure.

Referring to FIG. 6, a mask pattern of embodiments may include a second mesh structure MS2 formed by a first spacer S1 and a 2-2 spacer S2b. The 2-2 spacer S2b may be formed on the first spacer S1. The first mesh structure MS1 may define a plurality of first openings O1 and a plurality of second openings O2 formed by the first spacer S1 and the 2-2 spacer S2b.

The first spacer S1 may be formed by a first SPT process. The 2-2 spacer S2b may be formed by a second SPT process. The first SPT process and the second SPT process may be illustrated in detail later.

Hereinafter, the mask pattern including the first mesh structure MS1 formed using the first spacer S1 and the 2-1 spacer S2a may be illustrated.

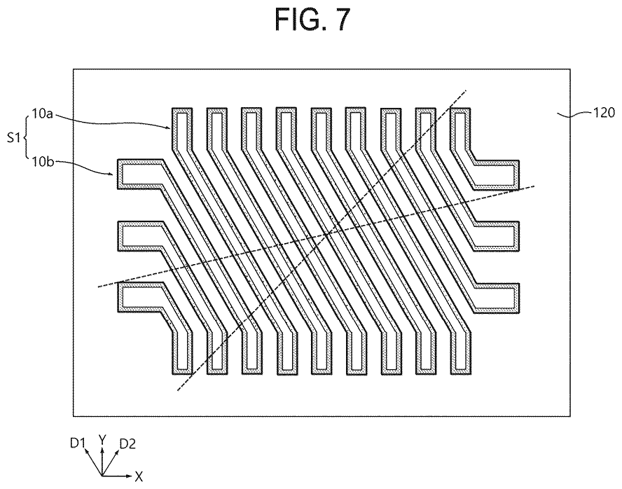

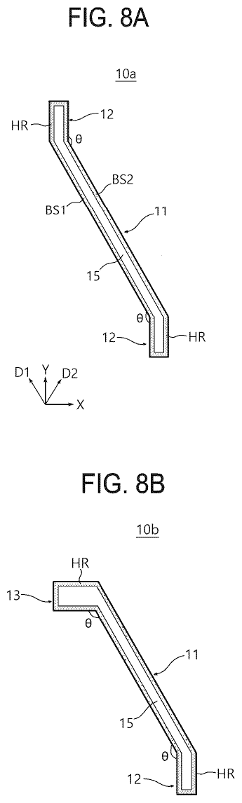

FIG. 7 is a plan view illustrating a first spacer formed on an etching target layer according to embodiments of the present disclosure, FIG. 8A is an enlarged plan view illustrating a first loop-shaped pattern of the first spacer of FIG. 7. FIG. 8B is an enlarged plan view illustrating a second loop-shaped pattern of the first spacer of FIG. 7.

Referring to FIG. 7, the first spacer S1 may be formed on the etching target layer 120. The first spacer S1 may include a plurality of first loop-shaped patterns 10a and a plurality of second loop-shaped patterns 10b. Each of the first and second spacers 10a and 10b may have a central region and an end region at both ends of the central region. The central regions of the first loop-shaped patterns 10a and the second loop-shaped patterns 10b may extend in a first diagonal direction D1 and may be referred to as first diagonal pattern portions 11. The second loop-shaped patterns 10b may be arranged at both sides of the first loop-shaped patterns 10a in a point symmetric structure base on a center point CP.

Referring to FIG. 8A, the first loop-shaped pattern 10a may include the first diagonal pattern portion 11 and a first longitudinally indented pattern portion 12. For example, the first diagonal pattern portion 11 may extend in the first diagonal line D1. The first longitudinally indented pattern portion 12 may be formed at both ends of the first diagonal pattern portion 11. The first longitudinally indented pattern portions 12 may extend in the longitudinal direction Y. The first loop-shaped pattern 10a may include an opening 15 formed at central portions of the first diagonal pattern portion 11 and the first longitudinally indented pattern portion 12.

Referring to FIG. 8B, the second loop-shaped pattern 10b may include the first diagonal pattern portion 11, a first longitudinally indented pattern portion 12 and a first horizontally indented pattern portion 13.

The first diagonal pattern portion 11 may be extended in the first diagonal line D1. The first longitudinally indented pattern portion 12 may be formed at one end of the first diagonal pattern portion 11. The first longitudinally indented pattern portion 12 may extend in the longitudinal direction Y. The first horizontally indented pattern portion 13 may be formed at the other end of the first diagonal pattern portion 11. The first horizontally indented pattern portion 13 may extend in the horizontal direction X. The second loop-shaped pattern 10b may include an opening 15 formed at central portions of the first diagonal pattern portion 11, the first longitudinally indented pattern portion 12 and the first horizontally indented pattern portion 13.

Particularly, the first diagonal pattern portion 11 may be extended in the first diagonal direction D1. The first diagonal pattern portion 11 may include two bar structures BS1 and BS2 which are spaced apart from each other. The first longitudinally indented pattern portion 12 and the first horizontally indented pattern portion 13 may include a semi-loop structure HR connected to both ends of the first diagonal pattern portion 11, respectively. For example, the semi-loop structure HR may be an opened-curve structure. The first loop-shaped pattern 10a may include the semi-loop structure HR connected to the bar structures BS1 and BS2 along the longitudinal direction. The second loop-shaped pattern 10b may include the semi-loop structure HR connected to both ends of the bar structures BS1 and BS2 in the longitudinal direction Y and the horizontal direction X.

The first longitudinally indented pattern portion 12 and the first horizontally indented pattern portion 13 may be extended from the two ends of the first diagonal pattern portion 11 at an obtuse angle. For example, an angle θ between the bar structures BS1 and BS and the semi-loop structure HR may be the obtuse angle.

Furthermore, the sizes of the first diagonal pattern portion 11, the first longitudinally indented pattern portion 12 and the first horizontally indented pattern portion 13 may adjust the sizes of the plurality of holes H.

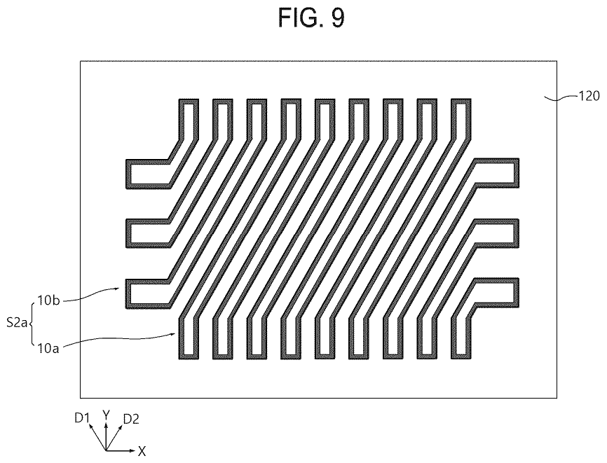

FIG. 9 is a plan view illustrating a 2-1 spacer formed on the etching target layer according to embodiments of the present disclosure.

Referring to FIG. 9, the 2-1 spacer S2a may be formed on the etching target layer 120. The 2-1 spacer S2a may include a first loop-shaped pattern 10a and a second loop-shaped pattern 10b.

A plurality of the first loop-shaped patterns 10a and a plurality of the second loop-shaped patterns 10b may be extended in a second diagonal direction D2 opposite to the first diagonal direction D1.

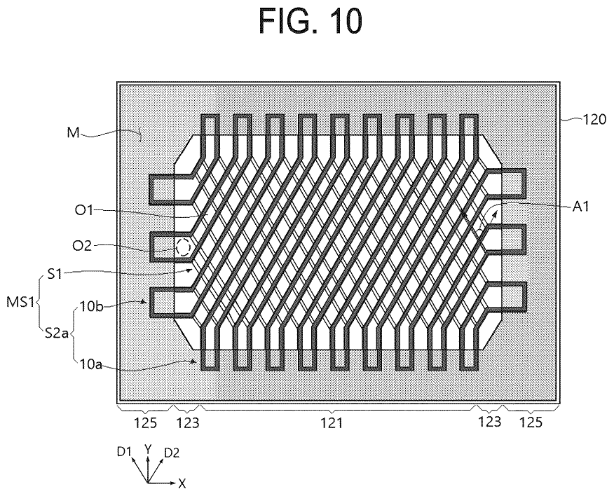

FIG. 10 is a plan view illustrating a mask pattern with a mask on a first mesh structure in accordance with embodiments of the present disclosure.

Referring to FIG. 10, the first mesh structure MS1 may include the first spacer S1 and the 2-1 spacer S2a formed on the first spacer S1. The first mesh structure MS1 may include a plurality of openings O1 and O2. The plurality of openings O1 and O2 may be defined by the central portions of the first and second loop-shaped patterns 10a and 10b in the first spacer S1 and the central portions of the first and second loop-shaped patterns 10a and 10b in the 2-1 spacer S2a. The two ends of the first spacer S1 may overlap with the two ends of the 2-1 spacer S2a. The first openings O1 may form a space where a plurality of holes may be formed after etching the etching target layer 120. The second openings O2 may form a space where a plurality of dummy holes may be formed after etching the etching target layer 120.

A mask M may be formed on the first mesh structure MS1. The mask M may determine a size of the second opening O2 (that is, the dummy hole) on the first mesh structure MS1.

Particularly, the mask M may cover parts of the two ends of the loop-shaped patterns 10a and 10b to define the size of the second opening O2. When an area of the mask M covering the two ends of the loop-shaped patterns 10a and 10b may be increased, the size of the second opening O2 may be decreased so that a size of the dummy hole may also be reduced. In contrast, when the area of the mask M covering the two ends of the loop-shaped opening O2 may be decreased, the size of the second opening O2 may be increased.

More particularly, the mask M may be positioned over the two ends of the loop-shaped patterns 10a and 10b to cover the two ends of the loop-shaped patterns 10a and 10b. The mask M may increase a margin between normal holes located at the outermost edge of the hole array region 121 and the dummy holes of a dummy hole region 123. For example, the size of the dummy hole may be adjusted by a size of an open region of the mask M. Furthermore, the mask M may increase the size of the dummy hole O2 to prevent the normal hole (hereinafter, edge normal hole) which is located at the outmost edge of the hole array region 121 from not being opened.

A plurality of holes for forming the hole array may be formed in the hole array region 121 by the first mesh structure SM1 and the mask M for forming the openings O1 and O2. The hole array region 121 may be positioned at the central portions of the loop-shaped patterns 10a and 10b. A size of the second opening O2 on the two ends of the loop-shaped patterns 10a and 10b may be controlled by the mask M to form the dummy holes.

In embodiments of the present disclosure, the size of the second opening O2 may be larger than the size of the first opening O1.

Particularly, the size of the second opening O2 may be from about 105% to about 200% of the size of the first opening O1. When a ratio of the area of the second opening O2 with respect to the area of the first opening O1 may be below about 105%, the edge normal hole may not be opened. In contrast, when the ratio of the area of the second opening O2 with respect to the area of the first opening O1 may be above about 200%, the bridge error may occur. That is, the size of the dummy hole formed by the second opening O2 may be larger than the size of the hole formed by the first opening O1.

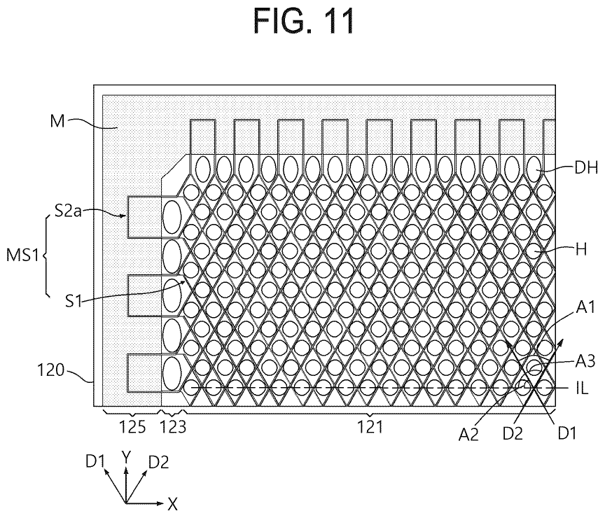

In embodiments of the present disclosure, in the first mesh structure MS1, the first diagonal direction D1 and the second diagonal direction D2 may be intersected with each other by an angle A (hereinafter, intersected angle). The intersected angle A1 between the first diagonal direction D1 and the second diagonal direction D2 may be from about 40° to about 90°. When the intersected angle A1 may be beyond the range (about 40° to about) 90°, the holes may not be formed at desired positions. An example of the holes formed by the first mesh structure MS1 can be seen in FIG. 11.

Particularly, the intersected angle A1 between the first diagonal direction D1 and the second diagonal direction D2 may be from about 50° to about 70°, preferably, about 60°.

Thus, in the first mesh structure MS1, the central portions of the loop-shaped patterns 10a and 10b of the first spacer S1 and the 2-1 spacer S2a may be extended in the different directions to have the mesh structure. In the first mesh structure MS1, the two ends and the central region of the loop-shaped patterns 10a and 10b may overlap with each other to form an intersection region and a non-intersection region. The non-intersection region may form the openings O1 and O2. And then, the etching target layer 120 may be selectively etched using the first mesh structure MS1 with the openings O1 and O2 to form the holes in the etching target layer 120.

FIG. 11 is a plan view illustrating a part region of an etching targe layer with a hole array and dummy holes formed using a mask on a first mesh structure in accordance with embodiments of the present disclosure.

Referring to FIG. 11, a plurality of holes H for the forming the hole array may be formed in the central portions of the loop-shaped patterns 10a and 10b, i.e., the hole array region 121 by the first mesh structure MS1 and the mask M. In the first mesh structure MS1, a plurality of dummy holes DH may be formed in the two ends of the loop-shaped patterns 10a and 10b, i.e., the dummy hole region 123.

In embodiments of the present disclosure, the first diagonal direction D1 and the second diagonal direction D2 may be inclined to an imaginary line IL, which may be connected between center points of the holes H in the horizontal direction X in the hole array region 121 of the etching target layer 120, at a predetermined angle. The horizontal direction X may be substantially parallel to the imaginary line IL. The longitudinal direction Y may be substantially perpendicular to the imaginary line IL.

Furthermore, an angle A2 between the first diagonal direction D1 and the imaginary line IL may be from about 40° to about 70°. An angle A3 between the second diagonal direction D2 and the imaginary line IL may be from about 110° to about 135°.

In drawings, the first spacer S1 may include the loop-shaped patterns 10a and 10b extended in the first diagonal direction D1. The 2-1 spacer S2a may include the loop-shaped patterns 10a and 10b extended in the second diagonal direction D2. Alternatively, the first diagonal line D1 and the second diagonal line D2 may be replaced with each other. That is, the first spacer S1 may include the loop-shaped patterns 10a and 10b extended in the second diagonal direction D2. The 2-1 spacer S2a may include the loop-shaped patterns 10a and 10b extended in the first diagonal direction D1.

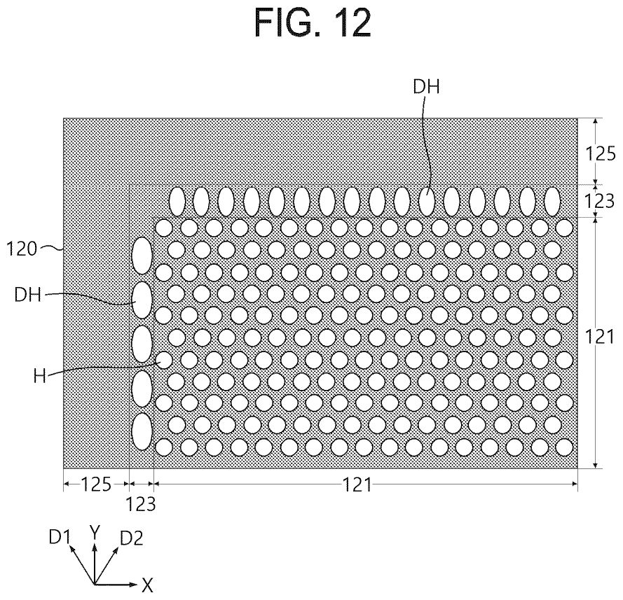

FIG. 12 is a plan view illustrating a part of an etching target layer with a hole array and dummy holes formed by a first mesh structure in accordance with embodiments of the present disclosure.

Referring to FIG. 12, the holes H and the dummy holes DH may be formed in the etching target layer 120 by the mask pattern.

Furthermore, the etching target layer 120 may include the hole array region 121, the dummy hole region 123 and a non-hole array region 125.

Particularly, the hole array including the plurality of holes H may be formed in the hole array region 121 at a center portion of the etching target layer 120 by the mask pattern. The dummy holes DH configured to surround the hole array region 121 may be formed in the dummy hole region 123 by the mask pattern. The holes H and the dummy holes DH may not be formed in the non-hole array region 125. The non-hole array region 125 may surround the dummy hole region 123. The dummy hole region 123 may be positioned between the hole array region 121 and the non-hole array region 125. For example, the non-hole array region 125 may be a peripheral region.

In embodiments of the present disclosure, the holes H may form a structure such as a storage node.

Referring again to FIG. 6, a mask pattern of embodiments may include the second mesh structure MS2 formed by the first spacer S1 and the 2-2 spacer S2b. The first spacer S1 may include a plurality of the first loop-shaped patterns 10a and a plurality of the second loop-shaped patterns 10b. The 2-2 spacer S2b may include a plurality of third loop-shaped patterns 10c. The third loop-shaped patterns 10c may be linearly extended in the horizontal direction X.

The first loop-shaped pattern 10a, the second loop-shaped pattern 10b and the third loop-shaped pattern 10c may have opened upper and lower surfaces. The third loop-shaped pattern 10c may be formed on the first and second loop-shaped patterns 10a and 10c. The mask pattern may include the second mesh structure MS2 by the first spacer S1 and the 2-2 spacer S2b to form the openings O1 and O2.

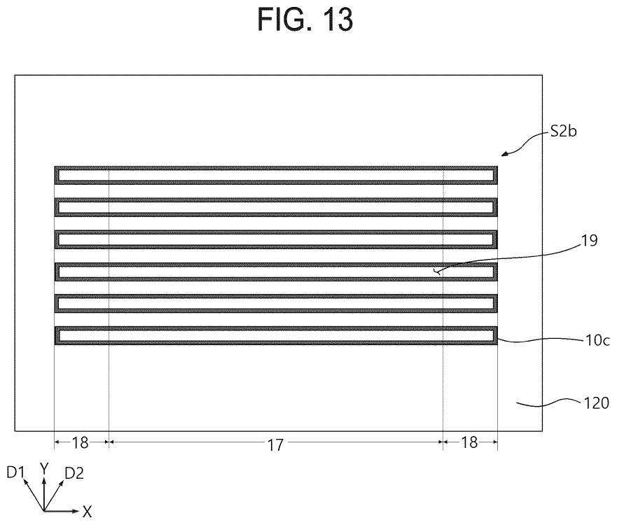

FIG. 13 is a plan view illustrating a 2-2 spacer formed on an etching target layer with a 2-2 spacer in accordance with embodiments of the present disclosure.

Referring to FIG. 13, the 2-2 spacer S2b may be formed on the etching target layer 120. The 2-2 spacer S2b may include the third loop-shaped patterns 10c having a rectangular-ring shape.

The third loop-shaped pattern 10c may include a line pattern portion 17 and a dummy pattern portion 18. The line pattern portion 17 may be formed in a central region of the third loop-shaped pattern 10c. The dummy pattern portion 18 may be formed at both ends of the line pattern portion 17 and may be aligned with the line pattern portion 17. The line pattern portion 17 and the dummy pattern portion 18 may have substantially the same width. Openings 19 having opened upper and lower surfaces may be formed through the central region of the third loop-shaped pattern 10c.

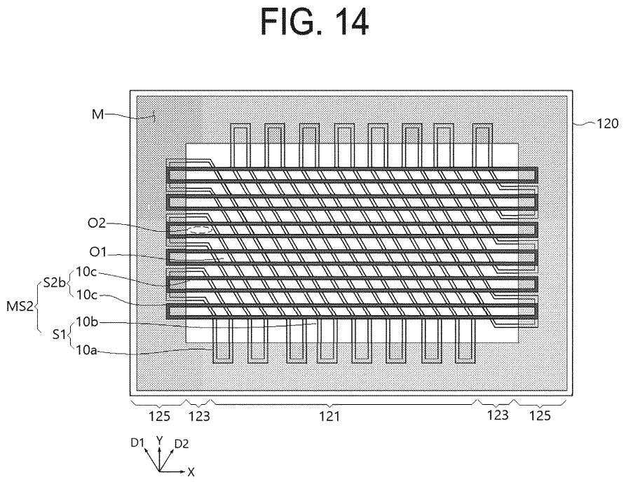

FIG. 14 is a plan view illustrating a mask pattern with a mask on a second mesh structure in accordance with embodiments of the present disclosure.

Referring to FIG. 14, a second mesh structure MS2 may include the first spacer S1 and the 2-2 spacer S2b formed over the first spacer S1. Thus, the central portions of the first and second loop-shaped patterns 10a and 10b of the first spacer S1 may be intersected with a central portion of the third loop-shaped pattern 10c of the 2-2 spacer S2b. Furthermore, the two ends of the first and second loop-shaped patterns 10a and 10b may overlap with the two ends of the third loop-shaped pattern 10c. Thus, the openings O1 and O2 may be formed over the etching target layer 120. The openings O1 and O2 may form a space where a hole or a dummy hole may be formed by etching the etching target layer 120.

A mask M may be formed on the second mesh structure MS2. The mask M may determine a size of the second opening O2 on the second mesh structure MS2.

In embodiments of the present disclosure, the mask pattern may adjust the sizes of the holes H and the dummy holes DH in the hole array by adjusting the widths of the line pattern portion 17 and the dummy pattern portion 18 in the third loop-shaped pattern 10c.

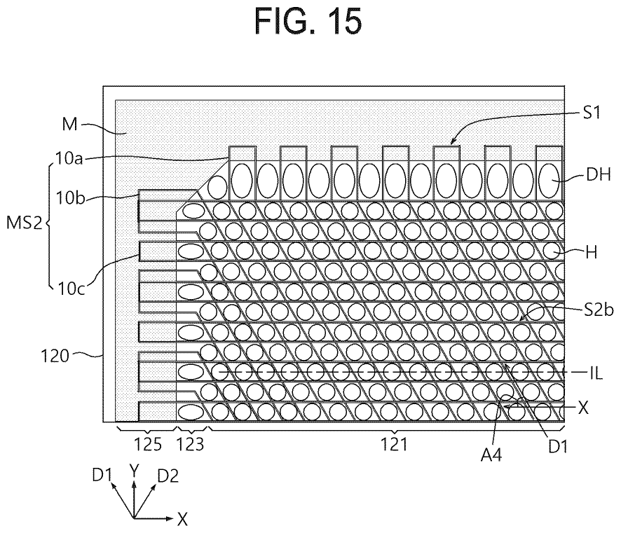

FIG. 15 is a plan view illustrating a part region of an etching targe layer with a hole array and dummy holes formed using a mask on a second mesh structure in accordance with embodiments of the present disclosure.

Referring to FIG. 15, the holes H may be formed in the hole array region 121. For example, the holes H may be defined by the central portions of the loop-shaped patterns 10a and 10c in the second mesh structure MS2, and the mask M. The dummy holes DH may be formed in the dummy hole region 123. For example, the dummy holes DH may be defined by the two ends of the loop-shaped patterns 10a and 10b, of the by the second mesh structure MS2, and the mask M.

In embodiments of the present disclosure, in the second mesh structure MS, the central portions of the first loop-shaped pattern 10a, the second loop-shaped pattern 10b and the third loop-shaped pattern 10c may be intersected with each other.

That is, an intersected angle A4 between the first diagonal direction D1 and the horizontal direction X of the third loop-shaped pattern 10c may be from about 45° to about 90°. When the intersected angle may be beyond the range (about 45° to about 90°), the holes may not be formed at desired positions. An example of the holes formed by the second mesh structure MS2 can be seen in FIG. 15.

Particularly, the intersected angle A4 between the first diagonal direction D1 and the horizontal direction X of the third loop-shaped pattern 10c may be from about 50° to about 70°, preferably, about 60°.

In, embodiments of the present disclosure, an area of the dummy hole DH may be larger than an area of the holes H in the hole array.

For example, a ratio of the area of the dummy hole DH with respect to the area of the holes H may be from about 105% to about 200%. When the area ratio may be below about 105%, the edge normal hole may not be opened. In contrast, when the area ratio may be above about 200%, the bridge error may occur.

In embodiments of the present disclosure, the positions of the loop-shaped patterns 10a, 10b and 10c may be replaced with each other. That is, the 2-2 spacer S2b in place of the first spacer S1 may be formed. The first spacer S1 may be formed on the 2-2 spacer S2b.

According to embodiments of the present disclosure, the mask pattern may utilize the spacers S1 and S2a. The spacers S1 and S2a may include the diagonal pattern, the indented pattern and the loop-shaped patterns 10 and 10b. The indented pattern may be extended from the two ends of the diagonal pattern in the horizontal direction or the longitudinal direction. The loop-shaped patterns 10a and 10b may include the openings. Alternatively, the mask pattern may utilize the spaces S1 and S2b including the loop-shaped patterns linearly extended in the horizontal direction. The mask pattern may utilize the spacers S1, S2a and S2b to secure the SPC process margin. The mask pattern may prevent the parasitic hole and the non-opened edge normal hole in forming the fine pattern of the semiconductor device. That is, sufficient space may be formed between the outermost holes and the dummy holes in the hole array region to secure the SPC process margin and to prevent forming a parasitic hole and q=a non-opened normal hole.

Furthermore, the mask pattern may use the mask M configured to determine the openings of the loop-shaped patterns 10a, 10b and 10c to control the sizes of the opened regions, thereby controlling the sizes of the dummy holes. Thus, the mask pattern may prevent an edge error of the hole array and the bridge between the holes.

Therefore, the method of forming the fine pattern of the semiconductor device using the mask pattern may manufacture the semiconductor device with the improved fine pattern.

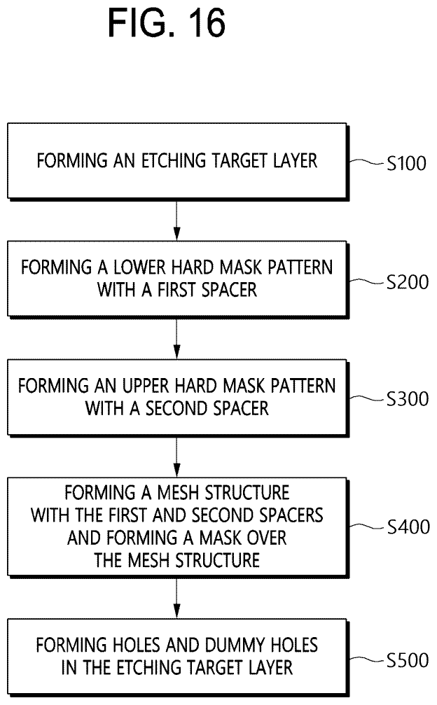

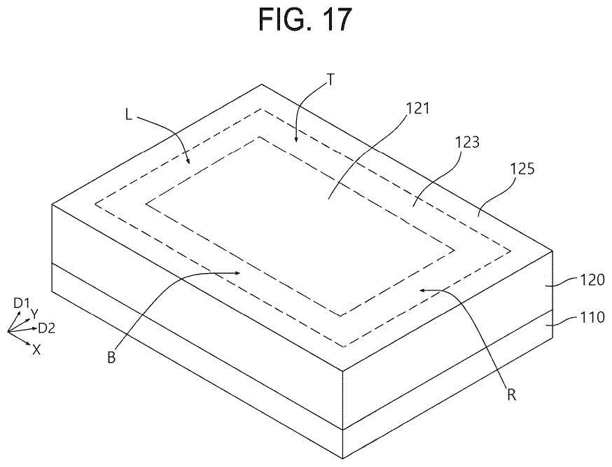

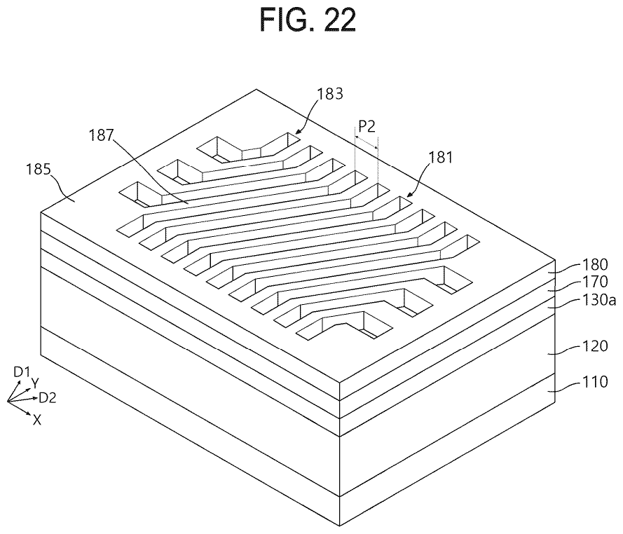

in accordance with embodiments of the present disclosure, FIG. 16 is a flow chart of a method of forming a fine pattern of a semiconductor device and FIGS. 17 to 26 are perspective views illustrating a method of forming a first mesh structure.

Referring to FIG. 16, a method of forming a fine pattern may include operation S100 for forming an etching target layer, operation S200 for forming a lower hard mask pattern with a first spacer, operation S300 for forming an upper had mask pattern with a second spacer, operation S400 for forming a mesh structure including the first and second spacers and forming a mask on the mesh structure, and operation S500 for forming holes and dummy holes in the etching target layer.

Referring to FIGS. 16 and 17, in operation S100, an etching target layer 120 may be formed on a substrate 110.

In embodiments of the present disclosure, the etching target layer 120 may include a material etched by a following etch process. For example, the etching target layer 120 may include a silicon layer, a metal layer, a silicon oxide layer, a silicon nitride layer, a combination thereof, etc. Particularly, the etching target layer 120 may include the silicon oxide layer.

Particularly, the etching target layer 102 may include phosphosilicate glass (PSG), borophosphosilicate glass (BPSG), undoped silicate glass (USG), tetra ethyl ortho silicate (TEOS), plasma enhanced-TEOS (PE-TEOS), high density plasma-chemical vapor deposition (HDP-CVD) oxide, a combination thereof, etc.

In embodiments of the present disclosure, the etching target layer 120 may include a plurality of regions.

For example, the etching target layer 120 may include a hole array region 121, a dummy hole region 123 and a non-hole array region 125.

A plurality of holes may be formed in the hole array region 121. The holes in the hole array region 121 may form an array with the holes spaced apart from each other at a regular pattern. The hole array region 121 may be formed in a center portion central region of the etching target layer 120. The dummy hole region 123 may surround the hole array region 121. Dummy holes may be formed in the dummy hole region 123. The holes and the dummy holes may not be formed in the non-hole array region 125. The non-hole array region 125 may surround the dummy hole region 123. The dummy hole region 123 may be positioned between the hole array region 121 and the non-hole array region 125.

In viewing the etching target layer on a planar plane, the positions of the dummy hole region 123 may be an upper side T, a lower side B, a left side L and a right side R in accordance with positions surrounding the hole array region 121.

The etching target layer 120 may be formed on the substrate 110. The substrate 110 may include a silicon substrate, a silicon germanium substrate, a silicon-on-insulator (SOI) substrate, etc. The substrate 110 may include a conductive layer, a conductive structure with a conductive layer, etc. The substrate 110 may include an impurity region, an upper insulation layer, etc.

In operation S200, the lower hard mask pattern including the first spacer may be formed on the etching target layer 120.

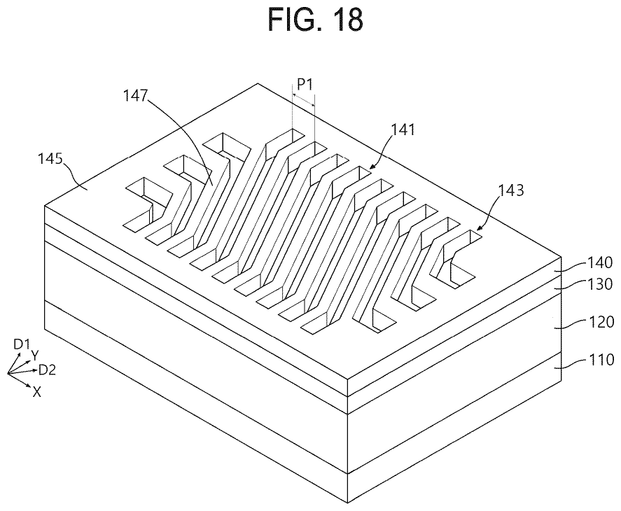

Referring to FIG. 18, a first hard mask layer 130 may be formed on the etching target layer 120. The first had mask layer 130 may include a material having an etching selectivity with respect to the etching target layer 120. For example, the first hard mask layer 130 may include silicon nitride or carbon. The first hard mask layer 130 may be formed by a CVD (chemical vapor deposition) or an ALD (atomic layer deposition), but is not limited thereto.

A first photoresist pattern 140 may be formed on the first hard mask layer 130. The first photoresist pattern 140 may include a plurality of first preliminary opening patterns 141 and a plurality of second preliminary opening patterns 143. For example, the first photoresist pattern 141 may be provided to form the first spacer S1. The first photoresist pattern 140 may be formed by a photolithography process. For example, each of the first and second preliminary opening patterns 141 and 143 may be repeatedly arranged spaced apart from each other by a first pitch P1. The first pitch P1 may be changed to adjust a diameter (or a width) of each of the holes H. Each of the first and second preliminary opening patterns 141 and 142 may include a diagonal pattern extended in the first diagonal direction D1 and an indented pattern extended from both ends of the diagonal pattern in the horizontal direction or the longitudinal direction. The indented pattern may be inclined to the two ends of the diagonal pattern at an obtuse angle.

The second preliminary opening pattern 143 may include a diagonal pattern, a longitudinally indented pattern and a horizontally indented pattern. The diagonal pattern may be extended in the first diagonal direction D1. The longitudinally indented pattern may be extended from one end of the diagonal pattern in the longitudinal direction inclined to the first diagonal direction D1 at an obtuse angle. The horizontally indented pattern may be extended from the other end of the diagonal pattern in the horizontal direction inclined to the first diagonal direction D1 at the obtuse angle. The horizontally indented pattern may have a width or an area greater than a width or an area of the longitudinally indented pattern.

The first photoresist pattern 140 may include a first preliminary body 145 and at least one first preliminary road 147. The first and second preliminary opening patterns 141 and 143 may be separated by the first preliminary road 147. The at least one first preliminary road 147 may be connected to the first preliminary body 145 to form one body.

The first hard mask layer 130 may be etched using the first photoresist pattern 140 as an etch mask. Thus, the first preliminary opening pattern 141, the second preliminary opening pattern 143, the first preliminary body 145 and the first preliminary road 147 may be transcribed into the first hard mask layer 130.

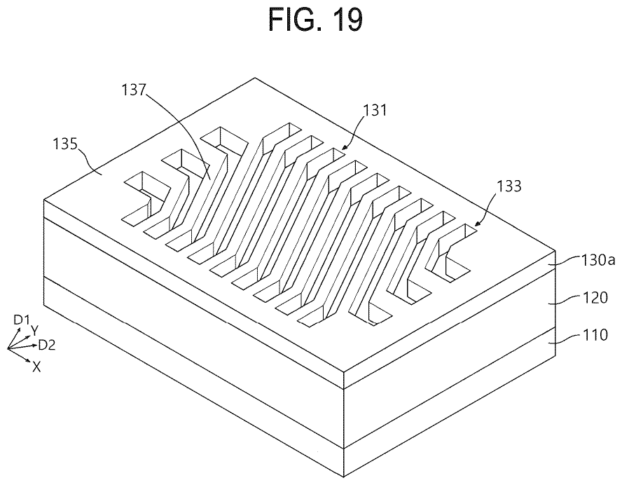

Referring to FIG. 19, the first photoresist pattern 140 may then be removed by a stripping process, to form a lower hard mask pattern 130a including a plurality of first opening patterns 131, a plurality of second opening patterns 133, a first body 135 and a first road 137.

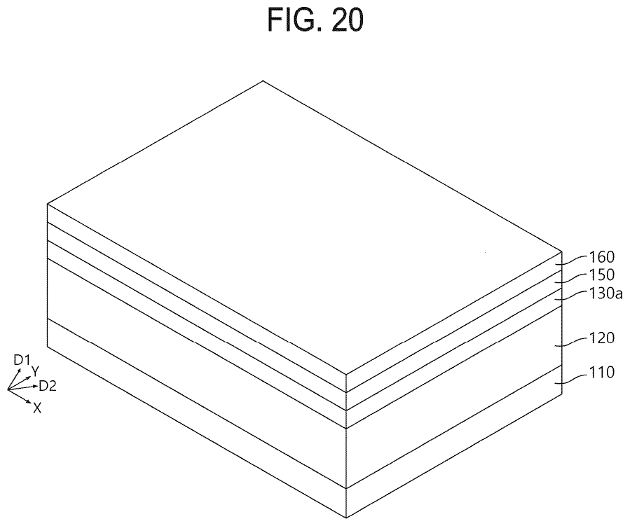

Referring to FIG. 20, a first spacer layer 150 may be formed on the lower hard mask pattern 130a. The first spacer layer 150 may include a material having an etching selectivity with respect to the lower hard mask pattern 130a. For example, the first spacer layer 150 may include silicon oxide. The first spacer layer 150 may be formed along the lower hard mask pattern 130a to have a uniform thickness so that the opening patterns 131 and 133 of the lower hard mask pattern 130a may not be filled with the first spacer layer 150.

A second hard mask layer 160 may be formed on the first spacer layer 150. The second hard mask layer 160 may include a material having an etching selectivity with respect to the first spacer layer 150. For example, the second hard mask layer 160 may include polysilicon. Alternatively, the material of the second hard mask layer 160 may be substantially the same as the material of the lower hard mask pattern 130a.

The first spacer layer 150 and the second hard mask layer 160 may be sequentially formed on the lower hard mask pattern 130a. A planarization process may be performed on the first spacer layer 150 and the second hard mask layer 160 to expose an upper surface of the lower hard mask pattern 130a.

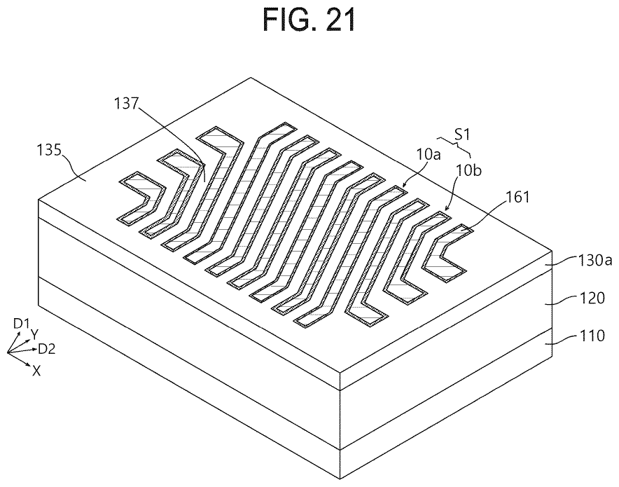

Referring to FIG. 21, the lower hard mask pattern 130a may include a first spacer S1 and a burying structure 161. The first spacer S1 may include a plurality of loop-shaped patterns 10a and 10b. The burying structure 161 is filled in the loop-shaped patterns 10a and 10b.

The process for forming the lower hard mask pattern 130a including the first spacer S1 with the loop-shaped patterns 10a and 10b may be a first SPT process.

Referring to again FIGS. 16 to 23, in operation S300, an upper hard mask pattern 170a including a 2-1 spacer S2a may be formed on the lower hard mask pattern 130a including the first spacer S1.

A third hard mask layer 170 may be formed on the lower hard mask pattern 130a. The third hard mask layer 170 may include a material having an etching selectivity with respect to the first spacer S1.

In embodiments of the present disclosure, the third hard mask layer 170 may include silicon nitride or carbon. The third hard mask layer 170 may be formed by the CVD or the ALD, but is not limited thereto. Particularly, the third hard mask layer 170 may include amorphous carbon.

A second photoresist pattern 180 may be formed on the third hard mask layer 170. The second photoresist pattern 180 may include a plurality of third preliminary opening patterns 181 and a plurality of fourth preliminary opening patterns 183 corresponding to the 2-1 spacer S2a. The second photoresist pattern 180 may be formed by a photolithography process. The third and fourth preliminary opening patterns 181 and 183 may be repeatedly arranged spaced apart from each other by a second pitch P2.

Particularly, a gap between the third preliminary opening patterns 181 and a gap between the fourth preliminary opening patterns 183 may be the second pitch P2. The second pitch P2 may be changed to adjust the diameter (or the width) of the hole H and the dummy hole DH.

The second photoresist pattern 180 may include a second preliminary body 185 and a second preliminary road 187. The second preliminary body 185 and the second preliminary road 187 may have functions substantially the same as the functions of the first preliminary body 145 and the first preliminary road 147. Thus, the functions of the second preliminary body 185 and the second preliminary road 187 may be omitted herein for brevity.

In the first and second photoresist pattern 140 and 180, each of the first preliminary opening pattern 141 and the third preliminary opening pattern 181 and each of the second preliminary opening pattern 143 and the fourth preliminary opening pattern 183 may have substantially the same width. The first preliminary opening pattern 141 and the third preliminary opening pattern 181 may have substantially the same pitch. The second preliminary opening pattern 143 and the fourth preliminary opening pattern 183 may have the substantially the same pitch. The first preliminary road 147 and the second preliminary road 187 may have substantially the same width.

The third hard mask layer 170 may be etched using the second photoresist pattern 180 as an etch mask. Thus, the third preliminary opening pattern 181 and the fourth preliminary opening pattern 183 may be transcribed into the third hard mask layer 170.

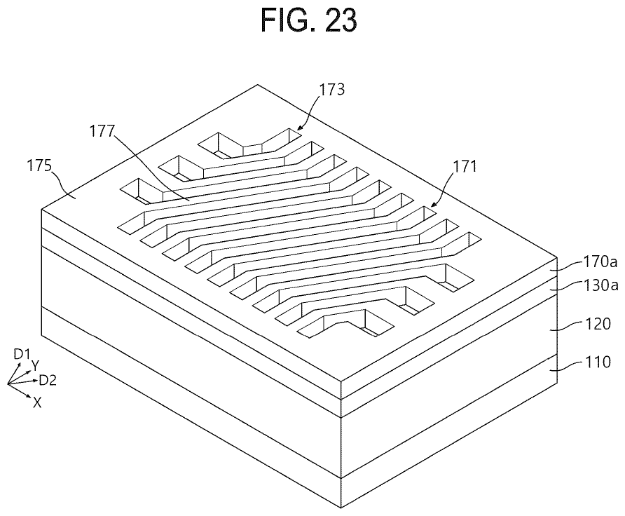

Referring to FIG. 23, the second photoresist pattern 180 may then be removed by a stripping process, to form an upper hard mask pattern 170a. The upper hard mask pattern 170a may include a plurality of third opening patterns 171, a plurality of fourth opening patterns 173, a second body 175 and a second road 177.

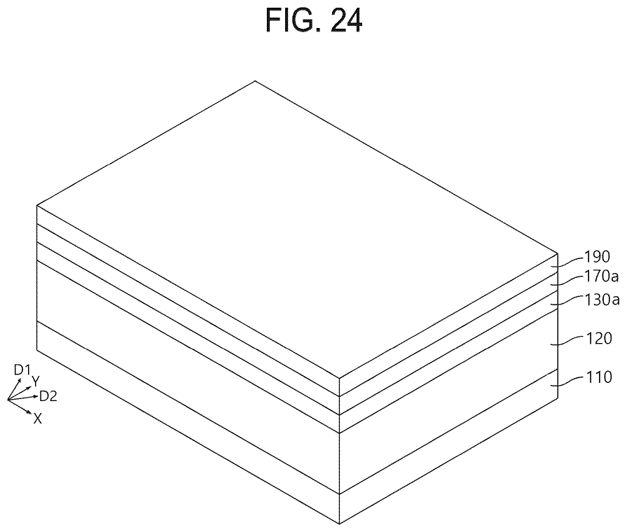

Referring to FIG. 24, a second spacer layer 190 may be formed on the upper hard mask pattern 170a. The second spacer layer 190 may include a material having an etching selectivity with respect to the upper hard mask pattern 170a. For example, the second spacer layer 190 may include silicon oxide. The second spacer layer 190 may have a conformal thickness. That is, the second spacer layer 190 may have a uniform thickness so that the opening patterns 171 and 173 of the upper hard mask pattern 170a may not be filled with the second spacer layer 190.

The second spacer layer 190 may be planarized to expose an upper surface of the upper hard mask pattern 170a.

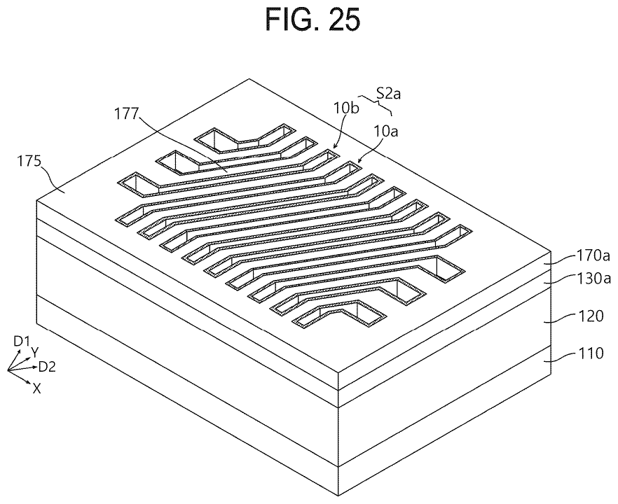

Referring to FIG. 25, the upper hard mask pattern 170a may include the 2-1 spacer S2a with the loop-shaped patterns 10a and 10b.

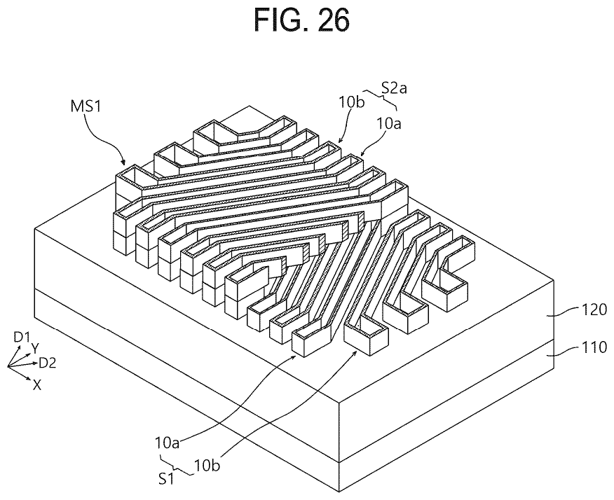

Referring to FIG. 26, the lower hard mask pattern 130a and the upper hard mask pattern 170a may then be removed to remain the first spacer S1 and the 2-1 spacer S2a stacked on the first spacer S1, to form the first mesh structure MS1.

In embodiments of the present disclosure, the process for forming the 2-1 spacer S2a may be a second SPT process.

Referring to FIG. 16, in operation S400, the mask M may be formed on the first mesh structure MS1 with the first spacer S1 and the 2-1 spacer S2a as the second spacer.

In operation S500, the etching target layer 120 may be etched using the first mesh structure MS1 as an etch mask to form the hole array with the holes and the dummy holes.

The method of forming the fine pattern of the semiconductor device may form the second mesh structure. In the method, the first spacer S1 may be formed by the first SPT process.

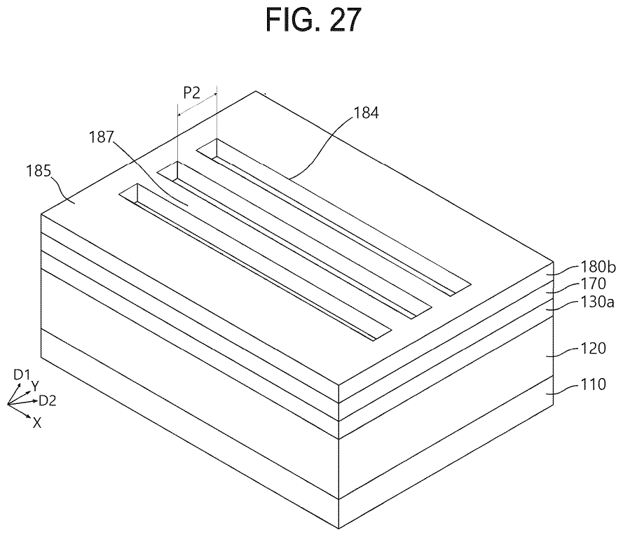

FIGS. 27 to 31 are perspective views illustrating a method of forming a second mesh structure in accordance with embodiments of the present disclosure.

Referring to FIG. 27, a third hard mask layer 170 may be formed on the lower had mask pattern 130a with the first spacer S1. The third hard mask layer 170 may include a material having an etching selectivity with respect to the first spacer S1.

A second photoresist pattern 180b may be formed on the third hard mask layer 170. The second photoresist pattern 180b may include a plurality of fifth preliminary opening patterns 184 having a shape corresponding to the shape of the 2-2 spacer S2b with the loop-shaped strip structure (see FIG. 13). The fifth preliminary opening patterns 184 may be repeatedly arranged spaced apart from each other by the second pitch P2. The second photoresist pattern 180 may include a second preliminary body 185 and a second preliminary road 187. The second preliminary body 185 and the second preliminary road 187 may have functions substantially the same as the functions of the first preliminary body 145 and the first preliminary road 147, respectively. Thus, any further illustrations with respect to the functions of the second preliminary body 185 and the second preliminary road 187 may be omitted herein for brevity.

The third hard mask layer 170 may be etched using the second photoresist pattern 180b to transcribe the fifth preliminary opening patterns 184, the second preliminary body 185 and the second preliminary road 187 into the third hard mask layer 170.

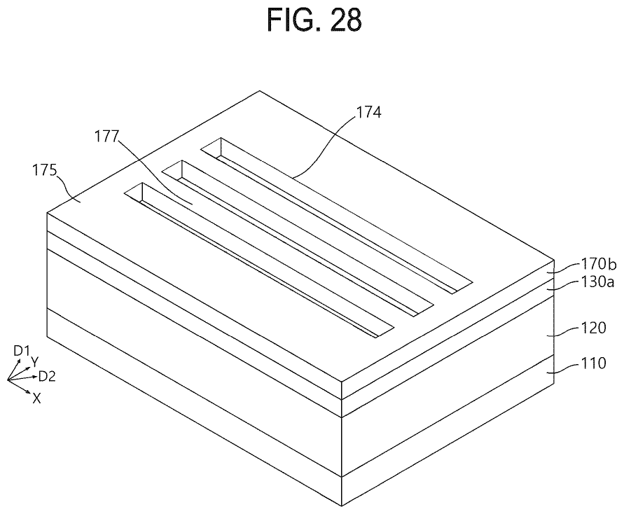

Referring to FIG. 28, a third hard mask pattern 170b with a plurality of fifth opening patterns 174 may be formed. The third hard mask pattern 170b may include a second body 175 and a second road 177.

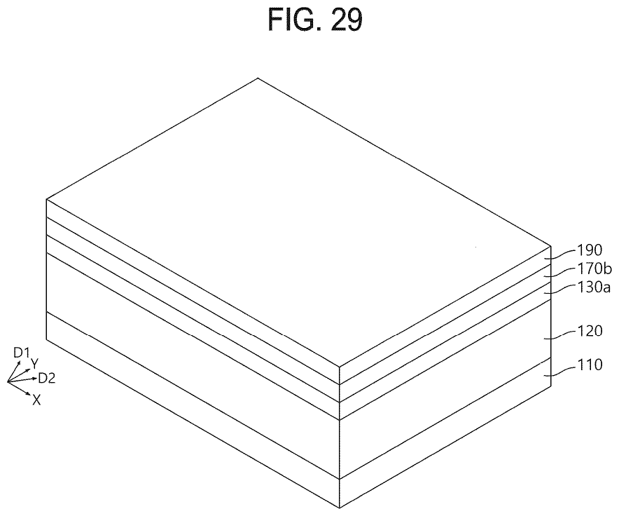

Referring to FIG. 29, a second spacer layer 190 may be formed on the third hard mask pattern 170b. The second spacer layer 190 may include a material having an etching selectivity with respect to the third hard mask pattern 170b. For example, the second spacer layer 190 may include silicon oxide. The second spacer layer 190 may be formed to have a uniform thickness so that the fifth opening patterns 174 may not be filled with the second spacer layer 190.

The second spacer layer 190 may be planarized to expose an upper surface of the third hard mask pattern 170b.

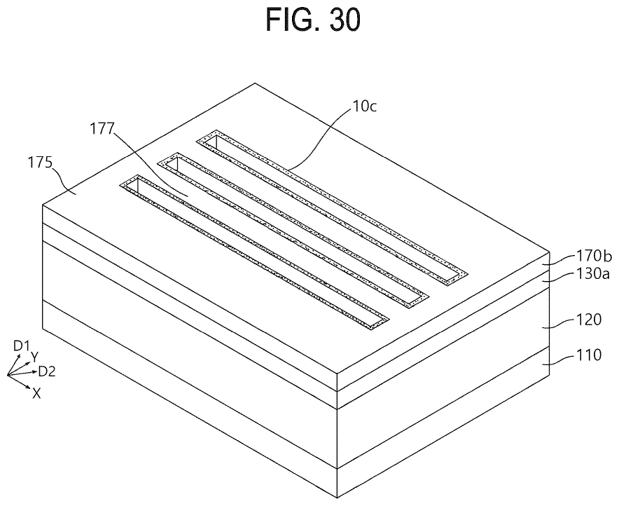

Referring to FIG. 30, a second upper hard mask pattern 170b may be formed on the lower hard mask pattern 130a. The second upper hard mask pattern 170b may include the 2-2 spacer S2b with the third loop-shaped patterns 10c.

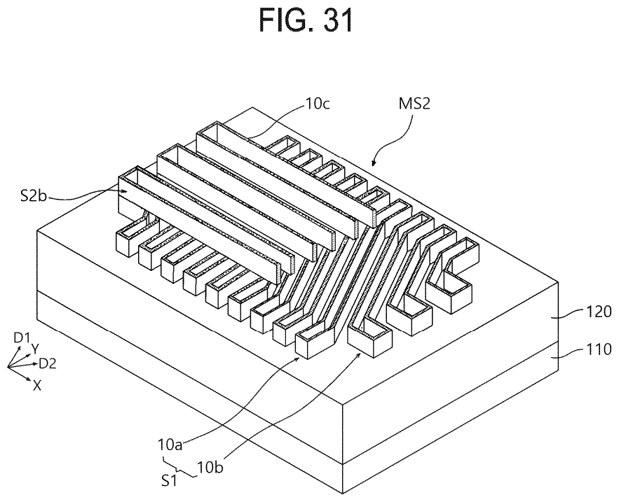

Referring to FIG. 31, the lower hard mask pattern 130a and the second upper hard mask pattern 170b may then be removed to remain the first spacer S1 and the 2-2 spacer S2b stacked on the first spacer S1, to form the second mesh structure MS2. The 2-2 spacer S2b includes the third loop-shaped patterns 10c extending to the horizontal direction X. For reference, the third loop-shaped patterns 10c are partially shown for convenience of description in FIG. 31.

A mask M for covering the non-hole array region may be formed on the second mesh structure MS2(See the FIG. 14). The etching target layer 120 may be etched using the second mesh structure MS2 and the mask M as an etch mask to form the hole array with the holes and the dummy holes. An example of the mask M can be found in FIG. 15, etc.

According to embodiments of the present disclosure, the mask pattern may use the spacer with the loop-shapes patterns, which may include the two diagonal patterns and the indented patterns extended in at least one of the horizontal direction and the longitudinal direction, and the openings, to secure the SPC process margin, thereby preventing the generations of the parasitic hole and the non-opened edge normal hole.

Furthermore, the sizes of the dummy holes may be controlled by adjusting the area of the mask for covering the non-hole array region. Furthermore, the bridge error may be prevented by adjusting the area of the mask for covering the non-hole array region.

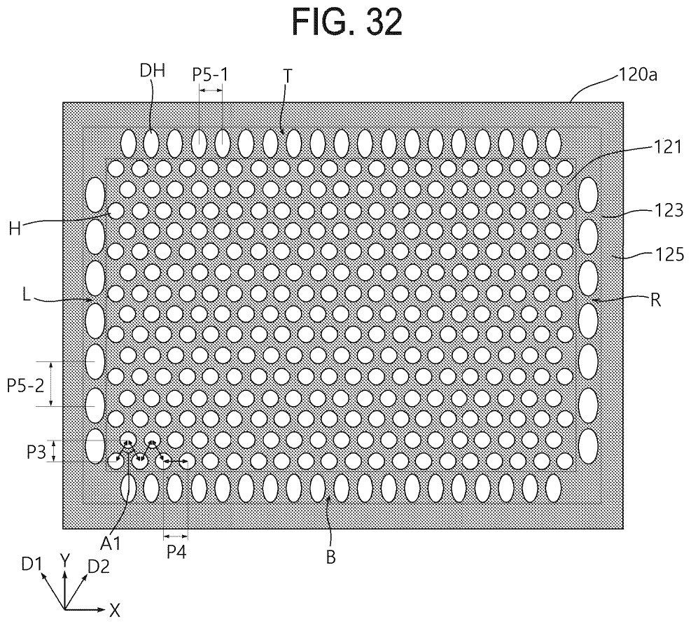

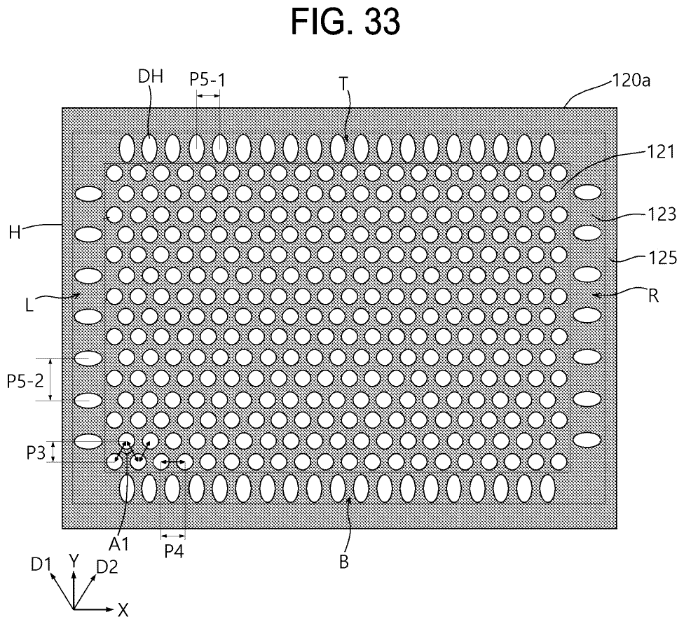

FIGS. 32 and 33 are plan views illustrating a semiconductor device with an etching target layer in accordance with embodiments of the present disclosure.

Referring to FIGS. 32 and 33, a semiconductor device of embodiments may include an etching target layer 120a. The etching target layer 120a may include a hole array region 121 and a dummy hole region 123. The etching target layer 120a may further include a non-hole region 125 configured to surround the dummy hole region 123.

The hole array region 121 may include a plurality of holes H. The holes H may be repeatedly arranged and spaced apart from each other by a third pitch P3 in the second diagonal direction D2. The holes H may be used for forming a structure such as a storage node.

Furthermore, the holes H may be spaced apart from each other by a fourth pitch P4 along the horizontal direction X.

The third pitch P3 may be substantially the same as the fourth pitch P4. Alternatively, the third pitch P3 may be different from the fourth pitch P4.

In embodiments of the present disclosure, an intersected angle between the first diagonal direction D1 and the second diagonal direction D2 may be from about 50° to about 70°.

The dummy hole region 123 may include a plurality of dummy holes DH. The dummy holes DH may be repeatedly arranged spaced apart from each other in the edge region of the hole array region 121 along the horizontal direction and the longitudinal direction by fifth pitches P5-1 and P5-2, respectively.

Particularly, the dummy holes DH may be repeatedly arranged spaced apart from each other at the upper side T and the lower side B in the edge region of the hole array region 121 along the horizontal direction X by the 5-1 pitch P5-1. The dummy holes DH may be repeatedly arranged spaced apart from each other at the left side L and the right side R in the edge region of the hole array region 121 along the longitudinal direction Y by the 5-2 pitch P5-2. The 5-1 pitch P5-1 may be substantially equal to or different from the 5-2 pitch P5-2.

A size and a shape of the dummy holes DH at the upper side T and the lower side B may be different from a size and a shape of the dummy holes DH at the left side L and the right side R in FIGS. 28 and 29.

The hole array region 121 with the holes H and the dummy hole region 123 with the dummy holes DH may be formed using the mask pattern.

The above described embodiments of the present disclosure are intended to illustrate and not to limit the present invention. Various alternatives and equivalents are possible. The invention is not limited by the embodiments described herein. Nor is the invention limited to any specific type of semiconductor device. Additions, subtractions, or modifications to the within embodiments which are apparent in view of the present disclosure are intended to fall within the scope of the appended claims. Furthermore, the embodiments may be combined to form additional embodiments.

What is claimed is:

1. A mask pattern comprising:
a first spacer formed over an etching target layer; and
a second spacer formed over the first spacer,
wherein a plurality of openings of a mesh structure formed by the first spacer and the second spacer are etched to form a hole array region including a plurality of holes and a plurality of dummy holes configured to surround the hole array region,
wherein at least one of the first spacer and the second spacer comprises a plurality of loop-shaped patterns with opened upper and lower surfaces, and
wherein each of the loop-shaped patterns comprises a diagonal pattern portion and an indented pattern portion, the diagonal pattern portion is extended in a diagonal direction inclined to an imaginary line connected between center points of the holes in the hole array region extended in a horizontal direction, and the indented pattern portion is extended from both ends of the diagonal pattern portion in the horizontal direction or a longitudinal direction.

2. The mask pattern of claim 1,
wherein the first spacer is formed on the etching target layer;
wherein the second spacer is formed on the first spacer, and
wherein each of the dummy holes has an area larger than an area of each of the holes in the hole array region.

3. The mask pattern of claim 1, wherein each of the dummy holes has an area of about 105% to about 200% of an area of each of the holes in the hole array region.

4. The mask pattern of claim 1, wherein the indented pattern portion has a width wider than a width of the diagonal pattern portion.

5. The mask pattern of claim 1,
wherein the first spacer comprises a plurality of loop-shaped patterns with opened upper and lower surfaces, each of the loop-shaped patterns comprises a diagonal pattern portion and an indented pattern portion, the diagonal pattern portion is extended in a first diagonal direction, and the indented pattern portion is extended from both ends of the diagonal pattern portion in the horizontal direction or the longitudinal direction,
wherein the second spacer comprises a plurality of loop-shaped patterns with opened upper and lower surfaces, each of the loop-shaped patterns comprises a diagonal pattern portion and an indented pattern portion, the diagonal pattern portion is extended in a second diagonal direction, and the indented pattern portion is extended from both ends of the diagonal pattern portion in the horizontal direction or the longitudinal direction, and
wherein the diagonal pattern portion in the first diagonal direction is intersected with the diagonal pattern portion in the second diagonal direction, and the indented pattern portion of the first pacer is overlapped with the indented pattern portion of the second spacer to form the plurality of openings of the mesh structure.

6. The mask pattern of claim 5, further comprising a mask arranged over the mesh structure to determine sizes of the opened regions formed by overlapping the indented pattern portion of the first spacer with the indented pattern portion of the second spacer.

7. The mask pattern of claim 6,
wherein the holes in the hole array region are formed in the opened regions formed by intersecting the diagonal pattern portion in the first diagonal direction with the diagonal pattern portion in the second diagonal direction, and
wherein the dummy holes are formed in the openings formed by overlapping the indented pattern portion of the first spacer with the indented pattern portion of the second spacer, and each of the dummy holes has a size determined by the mask.

8. The mask pattern of claim 1,
wherein the first spacer comprises a plurality of loop-shaped patterns with opened upper and lower surfaces, each of the loop-shaped patterns comprises a diagonal pattern portion and an indented pattern portion, the diagonal pattern portion is extended in a first diagonal direction, and the indented pattern portion is extended from both ends of the diagonal pattern portion in the horizontal direction or the longitudinal direction,
wherein the second spacer comprises a plurality of loop-shaped patterns with opened upper and lower surfaces, each of the loop-shaped patterns comprises a line pattern portion and a dummy pattern portion, the line pattern portion is horizontally extended in the horizontal direction, and the dummy pattern portion is horizontally extended from both ends of the line pattern portion, and
wherein the diagonal pattern portion of the first spacer is intersected with the diagonal pattern portion of the second spacer, and the indented pattern portion of the first pacer is overlapped with the indented pattern portion of the second spacer to form the plurality of openings of the mesh structure.

9. The mask pattern of claim 8, further comprising a mask arranged over the mesh structure to determine sizes of the opened regions formed by overlapping the indented pattern portion of the first spacer with the indented pattern portion of the second spacer.

10. A method of forming a fine pattern of a semiconductor device, the method comprising:
providing an etching target layer over a substrate;
forming a lower hard mask pattern on the etching target layer, the lower hard mask pattern including a first spacer with a plurality of loop-shaped patterns;
forming an upper hard mask pattern, which includes a second spacer with a plurality of loop-shaped patterns, on the lower hard mask pattern to form a mesh structure with a plurality of openings;
forming a mask over an edge region of the mesh structure to expose a dummy hole region and a hole array region; and
etching the etching target layer using the lower hard mask pattern, the upper hard mask pattern and mask to form a plurality of holes and a plurality of dummy holes in the etching target layer,
wherein at least one of the first spacer and the second spacer comprises a plurality of loop-shaped patterns with opened upper and lower surfaces, and
wherein each of the loop-shaped patterns comprises a diagonal pattern portion and an indented pattern portion, the diagonal pattern portion is extended in a diagonal direction inclined to an imaginary line connected between center points of the holes in the hole array region extended in a horizontal direction, and the indented pattern portion is extended from both ends of the diagonal pattern portion in the horizontal direction or a longitudinal direction.

11. The method of claim 10,
wherein the first spacer comprises a plurality of loop-shaped patterns with opened upper and lower surfaces, each of the loop-shaped patterns comprises a diagonal pattern portion and an indented pattern portion, the diagonal pattern portion is extended in a first diagonal direction, and the indented pattern portion is extended from both ends of the diagonal pattern portion in the horizontal direction or the longitudinal direction,
wherein the second spacer comprises a plurality of loop-shaped patterns with opened upper and lower surfaces, each of the loop-shaped patterns comprises a diagonal pattern portion and an indented pattern portion, the diagonal pattern portion is extended in a second diagonal direction, and the indented pattern portion is extended from both ends of the diagonal pattern portion in the horizontal direction or the longitudinal direction, and
wherein the diagonal pattern portion in the first diagonal direction is intersected with the diagonal pattern portion in the second diagonal direction, and the indented pattern portion of the first pacer is overlapped with the indented pattern portion of the second spacer to form the plurality of openings of the mesh structure.

12. The method of claim 11, wherein forming the lower hard mask pattern comprises:
forming a first hard mask layer on the layer;
forming a first photoresist pattern, which includes a plurality of first preliminary opening patterns and a plurality of second preliminary opening patterns, on the first hard mask pattern;
etching the first hard mask layer using the first photoresist pattern as an etch mask to form a first hard mask pattern including a first opening pattern and a second opening pattern;
forming a first spacer layer and a second spacer layer on the first hard mask pattern; and
partially removing the second hard mask layer and the first hard mask layer to form a lower hard mask pattern with a first spacer on the layer,
wherein the first spacer comprises a plurality of loop-shaped patterns with opened upper and lower surfaces, and
wherein each of the loop-shaped patterns comprises a diagonal pattern portion and an indented pattern portion, the diagonal pattern portion is extended in a first diagonal direction, and the indented pattern portion is extended from both ends of the diagonal pattern portion in the first diagonal direction.

13. The method of claim 11, wherein forming the mesh structure comprises:
forming a third hard mask layer on the lower hard mask pattern;
forming a second photoresist pattern, which includes a plurality of first preliminary opening patterns and a plurality of second preliminary opening patterns, on the third hard mask layer;
etching the first hard mask layer using the second photoresist pattern as an etch mask to form a third hard mask pattern including a first opening pattern and a second opening pattern;
forming a second spacer layer on the third hard mask pattern, the second spacer layer including a plurality of loop-shaped patterns with opened upper and lower surfaces, each of the loop-shaped patterns including a diagonal pattern portion on the indented pattern portion, and the diagonal pattern portion extended in a second diagonal direction; and
partially removing the third hard mask layer and the second spacer layer to form an upper hard mask pattern with a second spacer on the layer, thereby forming a mesh structure with a plurality of opened regions by the first spacer and the second spacer.

14. The method of claim 13, wherein the indented pattern portion has a width wider than widths of the diagonal pattern portions in the first and second diagonal directions.

15. The method of claim 10,
wherein the first spacer comprises a plurality of loop-shaped patterns with opened upper and lower surfaces, each of the loop-shaped patterns comprises a diagonal pattern portion and an indented pattern portion, the diagonal pattern portion is extended in a first diagonal direction, and the indented pattern portion is extended from both ends of the diagonal pattern portion in the horizontal direction or the longitudinal direction,
wherein the second spacer comprises a plurality of loop-shaped patterns with opened upper and lower surfaces, each of the loop-shaped patterns comprises a line pattern portion and a dummy pattern portion, the line pattern portion is horizontally extended in the horizontal direction, and the dummy pattern portion is horizontally extended from both ends of the line pattern portion, and
wherein the diagonal pattern portion of the first spacer is intersected with the diagonal pattern portion of the second spacer, and the indented pattern portion of the first pacer is overlapped with the indented pattern portion of the second spacer to form the plurality of openings of the mesh structure.

16. The method of claim 10, wherein forming the mesh structure comprises:
forming a third hard mask layer on the lower hard mask pattern;
forming a second photoresist pattern, which includes a plurality of third preliminary opening patterns, on the third hard mask layer;
etching the first hard mask layer using the second photoresist pattern as an etch mask to form a third hard mask pattern including a third opening pattern;
forming a second spacer layer on the third hard mask pattern; and
partially removing the third hard mask layer and the second spacer layer to form an upper hard mask pattern with a second spacer on the layer, thereby forming a mesh structure with a plurality of opened regions,
wherein the second spacer comprises a plurality of loop-shaped patterns, and each of the loop-shaped patterns comprises the line pattern portion and a dummy pattern portion.

17. A semiconductor device comprising:
a hole array region including a plurality of holes repeatedly arranged by a first pitch along a first diagonal direction and a second diagonal direction intersected with the first diagonal direction; and
a dummy hole region including a plurality of first dummy holes and a plurality of second dummy holes, the first dummy holes repeatedly arranged by a second pitch at an upper side and a lower side of the hole array region along a horizontal direction, and the second dummy holes repeatedly arranged by a third pitch different from the second pitch at a left side and a right side of the hole array region along a longitudinal direction.

18. The semiconductor device of claim 17, wherein an intersected angle between the first diagonal direction and the second diagonal direction is about 50° to about 70°.

19. The semiconductor device of claim 17, wherein the holes are repeatedly arranged by a fourth pitch along the horizontal direction, and the first pitch is substantially equal to or different from the fourth pitch.

20. The semiconductor device of claim 17, wherein each of the first dummy holes has a size different from a size of each of the second dummy holes.
